(19) United States
(12) Patent Application Publication
(10) Pub. No.: US 2024/0417843 A1
(43) Pub. Date: Dec. 19, 2024

(54) METHOD FOR PRODUCING SILICON ELECTRODES AS ANODES FOR LITHIUM BATTERIES

(71) Applicant: NORCSI GMBH, Halle (DE)

(72) Inventors: Udo REICHMANN, Wilsdruff (DE); Marcel NEUBERT, Kreischa (DE); Andreas KRAUSE-BADER, Dresden (DE)

(73) Assignee: NORCSI GMBH, Halle (DE)

(21) Appl. No.: 18/682,029

(22) PCT Filed: Aug. 9, 2022
(86) PCT No.: PCT/EP2022/072295

§ 371 Date: Feb. 7, 2024

(30) Foreign Application Priority Data
Aug. 9, 2021 (DE) 10 2021 120 615.4

(51) Int. Cl. C23C 14/16; C23C 14/34; C23C 14/58; H01M 4/02; H01M 4/04; H01M 4/36; H01M 4/38; H01M 10/0525

(52) U.S. Cl. CPC C23C 14/16; C23C 14/34; C23C 14/5806; C23C 14/5813; H01M 4/0426; H01M 4/366; H01M 4/386; H01M 2004/027; H01M 10/0525

(57) ABSTRACT

The invention relates to a method for producing a silicon anode for lithium batteries, in which a silicon layer is deposited on a substrate, preferably copper, and is then subjected to short-term tempering. The object of the present invention is to provide a method which allows control of the proportions of silicon relative to silicide and metal, in which method a compromise should be found between the maximum proportion of pure silicon which must be available as active material for the intercalation of lithium, with at the same time a sufficient number of inactive regions to achieve stability and good electrical conductivity, and with a sufficient anode layer thickness with a high silicon content for a high capacitance. According to the invention, said object is achieved in a first approach by repeating the deposition of the silicon layer and the subsequent short-term tempering at least once.

The invention relates to a method for producing a silicon electrode as anode for lithium batteries, wherein a first silicon layer is deposited on a substrate, preferably copper, and is subsequently subjected to accelerated annealing.

Electrochemical energy storage is a vital cornerstone in the global efforts toward energy transition, serving to provide interim storage of fluctuating power generated by regenerative means and to make it available to static and mobile applications. Mitigating against raw materials-based scarcity and hence increasing costs for secondary batteries in particular requires not only a diversification of the energy storage concepts, but also new materials. These materials ought both to improve the technical performance of such energy storage concepts (including capacity, energy density, lifetime) and to minimize the costs of production. The latter can be ensured in particular through the use of readily available chemical elements, as represented by silicon, for which a broad technology basis already exists.

Batteries are electrochemical energy stores and are differentiated as primary and secondary batteries.

Primary batteries are electrochemical power sources in which chemical energy is converted irreversibly into electrical energy. A primary battery is therefore not rechargeable. Secondary batteries, also called accumulators, on the other hand, are rechargeable electrochemical energy stores in which the chemical reaction that takes place is reversible, enabling multiple use. During charging, electrical energy is converted into chemical energy, and on discharge it is converted back from chemical to electrical energy.

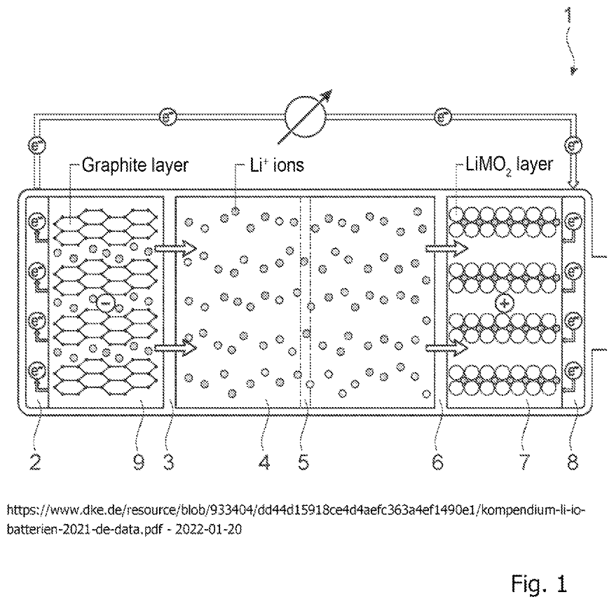

“Battery” is the headline term for interconnected cells. Cells are galvanic units which consist of two electrodes, electrolyte, separator, and cell casing. FIG. 1 shows an illustrative construction and the function of a lithium-ion cell during discharging. The constituents of a cell are briefly elucidated below.

Each Li-ion cell 1 consists of two different electrodes 7, 9: an electrode 7, which is negatively charged in the charged state, and an electrode 9, which is positively charged in the charged state. Since release of energy, in other words discharge, is accompanied by migration of ions from the negatively charged electrode to the positively charged electrode, the positively charged electrode is called the cathode 7 and the negatively charged electrode is called the anode 9. The electrodes are each composed of a current collector 2, 8 and of an active material applied thereon. Located between the electrodes are firstly the ion-conducting electrolyte 4, which enables the required exchange of charge, and the separator 5, which ensures electrical separation of the electrodes.

The cathode consists, for example, of mixed oxides applied on an aluminum collector. Transition metal oxides with cobalt (Co), manganese (Mn) and nickel (Ni) or aluminum oxide (Al₂O₃) are the most common compounds here. The applied metal oxide layer serves for intercalation of the lithium ions during discharge of the cell.

The anode of the Li-ion cell may consist of a copper foil as collector and of a layer of carbon as active material. The carbon compound used is usually natural or synthetic graphite, as it possesses a low electrode potential and exhibits little volume expansion during charging and discharging. During charging, lithium ions are reduced and intercalated into the graphite layers.

In constructions for lithium-ion batteries, the cathode typically supplies the lithium atoms for charging and discharge in the anode, and hence the battery capacity is limited by the cathode capacity. As already mentioned, typical cathode materials used to date are, for example, Li(Ni,Co,Mn)O₂ and LiFePO₄. Because of the construction of the cathode by lithium metal oxides, possibilities for boosting the capacity are minimal.

Also known for use with Li battery anodes is silicon rather than carbon. Silicon as an anode material has a high storage capacity of 3579 mAh/g at room temperature, as compared with the conventional carbon-type materials, such as graphite with a storage capacity of 372 mAh/g, for example. Challenges arise with the use of silicon as anode material, however, in terms of the sometimes considerable change in volume (volume contraction and expansion) of the host matrix during the intercalation and deintercalation of the mobile ion species during charging and discharge of corresponding energy stores. For graphite, the change in volume is around 10%, whereas for silicon it is around 400%. The change in volume of the anode material when silicon is used leads to internal stresses, cracking, pulverization of the active material of the host matrix (silicon), and ultimately complete destruction of the anode.

In order to lessen the change in volume, existing battery production methods make use of nanostructured, carbon- and/or silicon-based nanoparticles or nanowires as anode materials in chargeable lithium batteries. The major advantage of such nanomaterials, as well as increasing the rate of intercalation and deintercalation of the lithium, is the surface effect. What this effect means is that in the case of a large surface, the contact area for the electrolyte and the associated flow of Li+ ions (vacancies) is enlarged by the interface, as is described in the publication of M. R. Zamfir, H. T. Nguyen, E. Moyen, Y. H. Leeac and D. Pribat: Silicon nanowires for Li-based battery anodes: a review, Journal of Materials Chemistry A (a review), 1, 9566 (2013). Silicon-based nanoparticles and nanowires in particular exhibit relatively stable silicon structures in relation to the change in volume of the silicon after intercalation of lithium, up to a certain Si structure size, as is described in the publication of M. Green, E. Fielder, B. Scrosati, M. Wachtier and J. S. Moreno: Structured Silicon anodes for lithium battery applications, Electrochem. Solid-State Lett, 6, A75-A79 (2003). Regarded as a structural limit is 1 μm for amorphous silicon and 100 nm for crystalline silicon, allowing a uniform change in volume to take place.

Consequently, on the one hand, the volume expansion in the anode material can be covered by the free space between the nanostructures, while on the other hand the reduced size of the structures facilitates the phase transitions during alloy formation, so boosting the performance of the anode material.

The utilization of the silicon-based nanoparticles and nanowires, however, is very laborious. The Si nanostructures are produced both by physical and chemical methods, including ball milling, sputter deposition, PVD/CVD methods, chemical or electrochemical etching, and reduction of SiO₂ (Feng, K. et al. Silicon-Based Anodes for Lithium-Ion Batteries: From Fundamentals to Practical Applications. Small 14, 1702737 (2018)). Subsequently, according to the prior art, the nanostructures produced are mixed with conductive carbon and binder and are applied industrially to a copper current collector via calendering and drying to construct the anode. The disadvantage of these methods is that in battery operation, the nanostructures part from one another and so the anode loses capacitance. A further disadvantage is the large surface of the nanostructures, resulting in high consumption of electrolyte due to formation of an SEI (solid-electrolyte interphase) and in the battery drying out.

WO 2017/140581 A1 therefore describes a method for producing silicon-based anodes for secondary batteries that does not have these disadvantages. This method involves depositing, on a metal substrate serving as integrated current collector, a silicon layer and subsequently subjecting it to flash-lamp annealing. A flash-lamp process is usually used so as to melt silicon rapidly and locally and cause it to crystallize, in the semiconductor industry and for solar cells, for example. This, however, is not the goal of the method described in WO 2017/140581 A1. Instead, the flash-lamp annealing is employed as follows: generally speaking, crystallization of the silicon can be brought about only at around 700° C. This temperature is achieved with a flash-lamp anneal for a short time at the surface, with the rest of the substrate remaining significantly cooler. Even at temperatures which are significantly lower, from around 200° C., there is diffusion on the surface and along the grain boundaries in the metal substrate, since the covalent bonding of the Si atoms is weakened at the interface with a metal. This has already been demonstrated for multiple metal/semiconductor systems (e.g., Au/a-Si and Ag/a-Si) and has proven to be energetically favored, as described in the publication of Z. M. Wang, J. Y. Wang, L. P. H. Jeurgens and E. J. Mittemeijer: Thermodynamics and mechanism of metal-induced crystallization in immiscible alloy systems: Experiments and calculations on Al/a-Ge and Al/a-Si bilayers, Physical Review B 77, 045424 (2008). Furthermore, crystallization of the silicon can be achieved through the introduction of metal at comparatively low temperature. This is referred to as metal-induced crystallization. In very simple terms, crystalline growth is able to ensue after the temperature falls below the melting point, and this can be utilized as a criterion for phase transformation. With the method described in WO 2017/140581 A1, multiphase silicon-metal structures can be produced which absorb the change in volume brought about by delithiation and lithiation and which provide for stabilization of the entire material assembly. Lithiation refers to the intercalation of the lithium ions in the host material—for example, the silicon or the graphite.

The Si anodes which can be produced with the method known from WO 2017/140581 A1 are a mix of silicon, pure metals, and silicides, if only a copper foil is used as substrate and a silicon layer is deposited thereon—that is, a microstructure is formed which is composed of copper, copper silicide and silicon. The advantages of Si anodes produced in this way relative to Si anodes composed of nanoparticles or nanowires are a high electrical conductivity relative to pure silicon and also conventional graphite, since silicides have an electrical conductivity which is around two orders of magnitude better than that of graphite. Furthermore, the adhesion achieved between the Si layer as active material and the copper substrate is very good, with the copper diffusing from a copper foil into the deposited Si layer as a result of the flash-lamp annealing. The active regions for lithium intercalation, formed by the pure silicon, and the inactive regions, formed by the silicides/metals in the matrix, compensate the known, deleterious volume expansion during charging. Another advantage is that, because of the stratified construction, only a small area forms a boundary layer with the electrolyte; because of the low surface area, electrolyte decomposition is reduced relative to that occurring with nanostructured active material. Active material is the term for the silicon layer.

A disadvantage of the method described in WO 2017/140581 A1, however, is that because of the flash-lamp annealing, the Si layer undergoes uncontrolled reaction to form copper silicide, with the conversion reaction always beginning at the Cu—Si layer interface. As a result of the reaction, either there is no silicon left as active material for the intercalation of the lithium, or, if the energy input is so low, sufficient reaction does not take place and, in battery operation, the layer lacks adequate stability and so leads to a loss of capacity on the part of the battery. For a sufficient target capacity in the production of the lithium battery, sufficiently thick Si layers (10 μm corresponds to about 4 mAh/cm²) are necessary. If the conversion reaction of Cu+Si to form copper silicide is triggered in an uncontrolled way by an annealing method, including by flash-lamp annealing, the entire copper substrate, a copper foil for example, would react completely with the silicon to form copper silicide and would be accompanied by the loss of the current collector of the lithium battery.

The object of the present invention is therefore to specify a method which allows control of the proportions of silicon to silicide and metal. The intention was to find a trade-off between the maximum proportion of pure silicon, ideally amorphous or nanocrystalline, which must be available as active material for lithium intercalation, with at the same time a sufficient quantity of inactive regions to achieve stability and good electrical conductivity, and to provide for high capacity with a sufficient anode layer thickness with a high proportion of silicon.

The method ought also to permit control of the particular metal phase formed, e.g., Cu₅Si rather than Cu₃Si.

The object is achieved by a method in accordance with independent claim 1. In the method for producing a silicon electrode as anode for lithium batteries, wherein a first silicon layer is deposited on a substrate, preferably copper, and subsequently subjected to accelerated annealing, the deposition of a further silicon layer and the subsequent accelerated annealing are repeated at least once.

Accelerated annealing refers in particular to flash-lamp annealing and/or laser annealing. Flash-lamp annealing takes place with a pulse duration or annealing time in the range from 0.3 to 20 ms and a pulse energy in the range from 0.3 to 100 J/cm². In the case of laser annealing, the annealing time of 0.01 to 100 ms is established through the rate of scanning of the local heating site, to generate an energy density of 0.1 to 100 J/cm². The heating ramps achieved in the accelerated annealing are situated in the range, necessary for the method, of 10\hat{ }4-10\hat{ }7 K/s. Flash-lamp annealing for this purpose utilizes a spectrum in the visible wavelength range, whereas for laser annealing, discrete wavelengths in the range of the infrared (IR) to ultraviolet (UV) spectrum are used.

In one preferred embodiment of the method of the invention, the deposition of a further silicon layer and the subsequent accelerated annealing are repeated twice or more frequently. This allows layer thicknesses of several micrometers, preferably more than 5 μm, to be constructed without uncontrolled reaction of the entire layer construction to form copper silicide, which would entail a loss of the current collector.

The advantage of the repeated deposition of Si and the subsequent accelerated annealing is that each sequence is accompanied by formation of a stable (“reaction-neutralized”) layer, i.e., stratum, having a closed-off interface, which functions as an intermediate layer (interface) for the subsequent strata. This provides for a reduction in the proportion of copper in the layer, and hence after just two to three sequences, the copper-silicon reaction to form copper silicide does not proceed to completion: a gradient occurs in the proportion of copper, and pure silicon remains for a high capacitance. This is achieved because each stratum of the stratified structure with interface serves as a diffusion barrier for further layer construction. Additionally, with the accelerated annealing, each layer, i.e., stratum, can be individually annealed. The stratified structure may also be referred to and understood as a layer stack.

The method of the invention represents a very simple process for achieving very good adhesion at the interface between Cu collector and silicon, and also very good electrical transition. Other than the deposited silicon and the copper which comes from the copper collector, no additional material is required.

The described first variant embodiment of the method of the invention may be utilized as a preliminary process in combination with the other, following claimed method steps, since the roughening of the surface, as an example of a positive effect of a reaction separated stratum by stratum, results in good adhesion for further layers; the growth of column structures is promoted, allowing better ion conductivity to be achieved and allowing control over the proportion of copper for downstream processes. For example, the first layer may consist of 1 μm of silicon, which reacts completely with the copper substrate to form CuSiₓ, usually Cu₃Si. This causes roughening of the surface and very good adhesion to the copper substrate. While a part of the copper substrate is indeed consumed, the method of the invention means that, through the choice of the process parameters in the accelerated annealing, the reaction proceeds in a controlled manner, and loss of the current collector is prevented. The strong adhesion of the subsequently produced stratified construction on the copper substrate may also be realized through mechanical roughening or by means of a material other than silicon.

The very good adhesion to the substrate is critical to the subsequently applied multistratum not breaking off when there is a volume expansion due to the intercalation of lithium during battery operation. It is only by means of the method of the invention that stable battery operation is enabled.

This cannot be realized with the method described in WO 2017/140581 A1. In WO 2017/140581 A1 only one silicon layer is deposited and subjected to flash-lamp annealing. The necessary Si layer thickness of up to 10 μm for battery applications is deposited on the substrate in one process step and annealed by the flash lamp. However, the layers produced in this way are brittle and easily flake off or react completely with the copper of the substrate, leaving no storage-capable silicon.

In one advantageous embodiment of the method of the invention, before the deposition of the further silicon layer, a thin stratum of a further layer-layer other than silicon—is applied. This thin stratum of the further layer may be, for example, carbon, a metal, a metal oxide or a metal nitride; more particularly, the thin stratum of the further layer may be formed of one of the materials titanium (Ti), nickel (Ni), aluminum (Al), tin (Sn), gold (Au), silver (Ag), tungsten (W) and/or copper (Cu). A thin layer is one with a thickness of 5 to 200 nm. The thickness is defined as the thickness at which the desired function of the added stratum is deemed sufficient for the fabrication process, particularly the accelerated annealing.

The insertion of an additional material into the strata of the stratified silicon construction has the advantage that only a very small part of the copper in the copper substrate reacts with the applied layers, this having the particular effect of good adhesion, and, moreover, the copper in the current collector is not diminished, owing to the prevention of reaction with the other deposited layers.

It has emerged that the effect of the accelerated annealing, in the context of the deposition of a further layer other than the copper substrate material, is different, not least from copper additionally deposited onto the copper substrate. The cause is considered to be the wide variety of chemical events in connection with silicon. As a result, other structures can form in the anode layer generated: for example, column structures in the case of nickel, or dendrites in the case of copper. Dendrites are treelike or bushlike crystal structures. Also possible is the formation of other silicides, which—in contrast to Cu silicides, which have negligible capacity or no capacity for intercalation of lithium—do intercalate lithium. An advantage of exploiting the stated differences is that it allows the volume expansion of silicon on lithium intercalation to be controlled. As a result, the stability of battery operation is significantly increased.

In the case of nickel as a thin stratum of a further layer, before the deposition of the further silicon layer, nickel silicide is initially formed during the accelerated annealing. Where the accelerated annealing used is flash-lamp annealing, the nickel is substituted again by copper by means of a flash light lamp, which may have a flash light duration of between 0.2 ms and 20 ms and an energy density of 0.6 J/cm2 and 160 J/cm2, and nickel remains as the pure metal in the layer. Since nickel silicide has a relatively low density, relatively low-density Cu silicide is formed. This enhances the compensation on intercalation of Li. Where the accelerated annealing takes place by means of a laser (laser annealing), this is carried out with an annealing time in the range from 0.01 ms to 100 ms by the establishment of a rate of scanning of a local heating site and an energy density in the range from 0.1 to 100 J/cm² and also of preheating or cooling in the range from 4° C. to 200° C. The use of a flash lamp or a laser is required because the process is a non-equilibrium process which can be realized only in the ms range.

The flash lamps consist preferably of gas discharge lamps which emit a main fraction of the radiation in the wavelength range between the visible range and the infrared range (400 nm-800 nm) and operate with an approximate total power of around 12 MW in less than 20 ms, allowing the sample surfaces to be brought to a temperature of up to 2000° C. The purpose of the flash-lamp annealing is to promote the metal-induced layer exchange process, also known as metal-induced crystallization.

In the case of titanium, Ti silicide is formed, which in the correct phase may have Li intercalation capacity (see: Xu, J. et al. Preparation of TiSi₂ Powders with Enhanced Lithium-Ion Storage via Chemical Oven Self-Propagating High-Temperature Synthesis. Nanomaterials 11, 2279 (2021)). This has the advantage that there is no clear interface between Li-active and Li-inactive and consequently there is good electrical contact even during cycling. Further metals such as aluminum, for example, do not form any compound with silicon—that is, do not form any silicides. As a consequence of this, these metals mix in silicon and the electrical conductivity is increased. In the accelerated annealing step, there may additionally be improvements in the morphology and hardness of the silicon-metal layer relative to the hard pure silicon.

The carbon serves as a diffusion barrier for preventing the further uncontrolled reaction of the copper from the substrate/current collector with the following active layer. The active layer refers to the further silicon layer into which lithium can be intercalated.

The utilization of carbon has the advantage that carbon in the form of graphite is already utilized in the production of lithium-ion batteries and can therefore be integrated readily and compatibly into the production process. A further advantage is that the sputtered carbon can be employed as a copper diffusion barrier and so lessens the formation of silicide. Carbon has the advantage, moreover, that it is very lightweight and is electrically conductive, and is able to diffuse effectively through lithium. The weight, the good electrical and ionic conductivity are an advantage over all other metals for service in the intermediate layer. Carbon may also serve as a protective layer at the silicon/electrolyte interface, as it is chemically inert and, as already mentioned, possesses good Li+ ion conductivity.

In a further embodiment of the method of the invention, a metal layer is deposited onto the further silicon layer before the accelerated annealing. In addition to the properties mentioned so far, the possibility exists, with this variant according to the invention, of the surface of the active layer being roughened by the reaction with the metal. This may improve the ion conductivity and/or the electrolyte-active material boundary layer.

The deposition of an additional metal layer on the silicon layer therefore has the advantage that the silicide formation reaction takes place at the interface with the copper foil and additionally at the interface of the metal layer applied above. Hence effective adhesion between copper foil and silicon layer is further ensured and at the same time the reaction of Cu and Si to form copper silicide is controlled by the metal layer on the top side. A metal layer may improve the surface conductivity. Important for rapid charging/discharge procedures is a high electrical conductivity on the part of the battery, and the ability of the Li+ ions to penetrate the layers effectively. It is therefore necessary for all the layers and interfaces to have maximum conductivity. For example, Si in doped form may be highly conductive, but may react with the electrolyte and/or with degradation products, thus forming SiO₂ (very good insulator) or even Li₄SiO₄ (Li silicate). Li silicate is a very good insulator and strong bonding results in losses of Li. This must therefore be prevented in the overall anode construct, by means, for example, of noncontinuous/porous surfaces, conductive interfaces, soluble/soft protective layers. Exactly this can be prevented by an additional metal layer at the interface.

In one advantageous embodiment of the method of the invention, the metal layer is formed from one of the materials titanium (Ti), nickel (Ni), aluminum (Al), tin (Sn), gold (Au), silver (Ag) and/or tungsten (W). The advantages are those designated above.

In a further embodiment of the method of the invention, before the deposition of the first silicon layer on the copper substrate, a layer other than silicon is deposited, preferably nickel (Ni) and/or copper (Cu). This firstly has the advantage that it is possible by means of the accelerated annealing to adjust the extent to which the layer is to react, and secondly no copper of the current collector is used to form the copper silicide; instead, the formation of metal silicide takes place in a controlled manner between the applied metal layer, such as nickel or copper, for example, and the first silicon layer that is then deposited.

The invention will be elucidated in more detail below, with reference to exemplary embodiments.

In the drawings

FIG. 1 shows an illustrative construction and function of a lithium-ion cell during discharging;

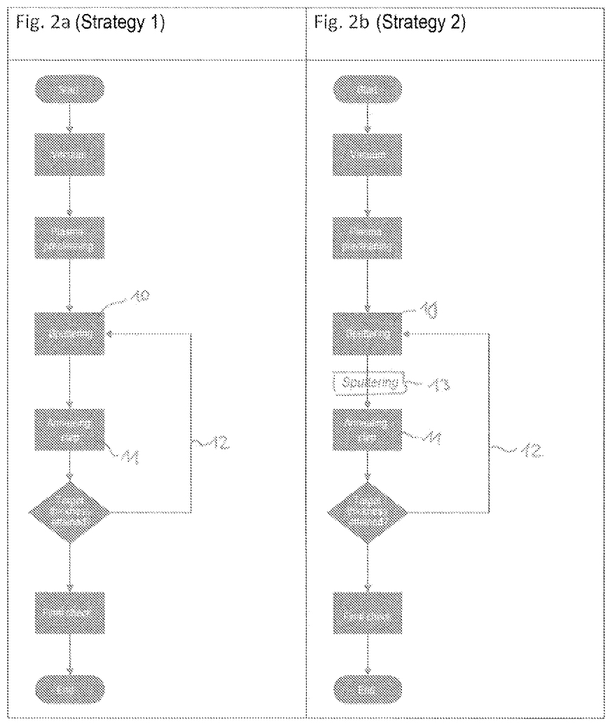

FIG. 2 shows a schematic representation of the method of the invention for producing a silicon anode for a lithium-ion battery:
a) repeated coating of the Cu substrate with silicon and subsequent accelerated annealing; b) deposition of a thin metal layer between the Cu substrate and the Si layer;

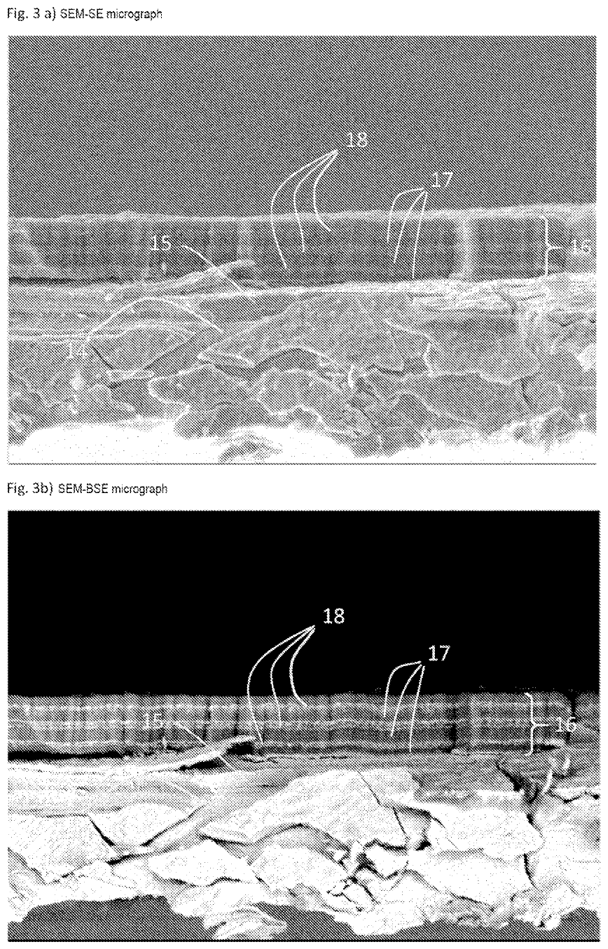

FIG. 3 a multistratum construction produced in accordance with the method of the invention for stabilizing the Si layer system: a) SEM-SE micrograph, b) SEM-BSE micrograph;

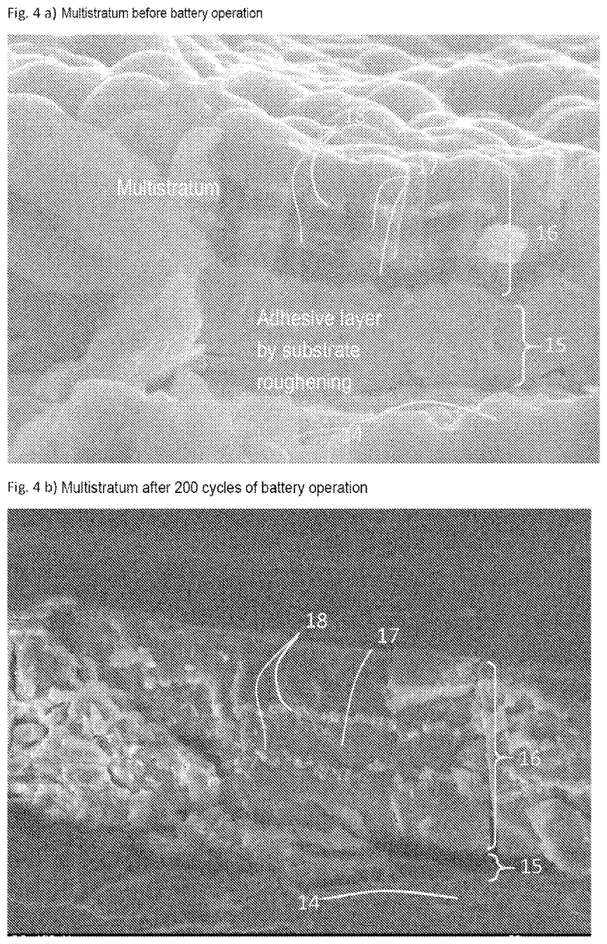

FIG. 4 shows a picture of a multistratum construction in accordance with the method of the invention a) before battery operation, b) after 200 cycles of battery operation;

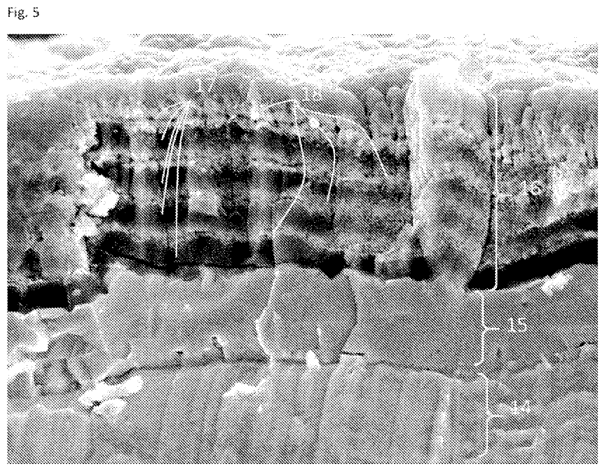

FIG. 5 shows a further picture of a multistratum construction in accordance with the method of the invention.

FIG. 2a shows the steps of the invention in a first method variant as a flow diagram. A substrate, serving simultaneously as current collector, undergoes precleaning under vacuum conditions in a plasma atmosphere. Construction of the silicon strata takes place subsequently via physical vapor deposition, e.g., sputtering or vaporization. This involves sequential application of an Si layer 10, with the strata being stabilized by accelerated annealing 11, e.g., flash-lamp annealing. The advantage of the repeated Si deposition 12 and subsequent accelerated annealing is that with each sequence a stable (“reaction-neutralized”) layer is formed with a closed-off interface, which functions as an intermediate layer (interface) for the subsequent strata.

FIG. 2b shows the steps of the invention in a second method variant as a flow diagram. A substrate, serving simultaneously as current collector, undergoes precleaning under vacuum conditions in a plasma atmosphere. Construction of the silicon strata takes place subsequently via physical vapor deposition, e.g., sputtering and/or vaporization, and the application of a thin stratum of a further layer other than silicon. This involves application first of an Si layer 10 and of a thin stratum of another material 13, e.g., carbon, a metal, a metal oxide or a metal nitride or copper, either onto the first silicon layer or on a further silicon layer, with the strata being stabilized by accelerated annealing 11. The advantage of the repeated Si deposition 12 and additional further layer and also the subsequent accelerated annealing is that in the case of titanium, for example, Ti silicide is formed, which in the correct phase may have Li intercalation facility. This has the advantage that there is no clear interface between Li-active and Li-inactive and consequently there is good electrical contact even during battery operation. Further metals such as aluminum, for example, do not form any compound with silicon—that is, do not form any silicides. As a consequence of this, these metals mix in silicon and the electrical conductivity is increased. In the annealing step, there may additionally be improvements in the morphology and hardness of the silicon-metal layer relative to the hard pure silicon.

The advantage of the repeated deposition of Si and the subsequent accelerated annealing is that each sequence is accompanied by a reduction in the proportion of copper in the layer, and hence after just two to three sequences, the copper-silicon reaction to form copper silicide does not proceed to completion, and pure silicon remains. This is achieved because each layer stack with interface serves as a diffusion barrier for further layer construction. Additionally, with the accelerated annealing, each layer can be individually annealed.

The method of the invention represents a very simple process for achieving very good adhesion at the interface between Cu collector and silicon, and also very good electrical transition. Other than the deposited silicon and the copper which comes from the copper collector, no additional material is required. Hence the battery capacity can be further boosted relative to lithium batteries produced by means of a conventional method. The deposition of a further silicon layer with subsequent accelerated annealing may be utilized as a preliminary process in combination with the deposition of a thin stratum of a further layer for the stratified silicon construction, since the roughening of the surface results in good adhesion for further layers; the growth of column structures is promoted, allowing better ion conductivity to be achieved and allowing control over the proportion of copper for downstream processes.

FIG. 3 shows two scanning electron microscope (SEM) micrographs of a multistratum construction produced in accordance with the method of the invention. FIG. 3a shows an SEM-SE micrograph (SE—secondary electrons), where on the copper substrate 14 a silicon layer with a thickness, for example, of 1 μm has been applied, this layer having developed, as a result of the accelerated annealing, more particularly flash-lamp annealing, with the copper substrate into a thin, rough, nonactive layer of fully reaction-neutralized CuSi_{X} as adhesive layer 15, on which an active layer has been deposited that is formed by a multistratum construction 16, with alternating deposition of silicon 17 and copper 18 and with the individual strata having been stabilized via the accelerated annealing. The copper layers significantly increase the adhesion of the stratified construction. The copper layers are recognizable as light-colored stripes in the SEM-BSE micrograph (BSE—backscattered electrons) in FIG. 3b. The layer thickness of the active layer (multistratum construction 16) may amount for example to 6 μm. At 2000 mAh/g, this corresponds to a capacitance of 2.4 mAh/cm². The function of the adhesive layer 15 may also be realized by mechanical roughening of the surface or by means of a material other than silicon.

FIG. 4a shows the picture of a multistratum construction 16 in accordance with the method of the invention before battery operation, and FIG. 4b shows the same multistratum construction 16 after 200 cycles of battery operation. Applied on a copper substrate 14 as adhesive layer 15 has been copper silicide, which has formed from a deposited silicon layer and the copper of the copper substrate as a result of accelerated annealing, more particularly flash-lamp annealing, this layer producing roughening of the substrate. Deposited thereon has been a multistratum construction 16 composed of three strata of silicon 17 and two strata of copper 18, with each intermediate layer (Si and Cu) being stabilized via accelerated annealing. Accelerated annealing may also be necessary only every two (or more) silicon strata. For example, in a first step, a multistratum construction of Si—Cu—Si is deposited, which is subjected to accelerated annealing, and subsequently further strata of Cu and Si are deposited, which are in turn subjected to accelerated annealing. The method of the invention is very variable. The lesser the frequency of flash/laser treatment and, correspondingly, the greater the amount of energy saved, the more cost-effective the overall process. Even after 200 cycles of battery operation, the multistratum construction 16 is preserved and is recognizable. The surface is smooth and stable. With the method of the invention, a stable active layer 10 μm thick can be produced for the anode, this corresponding to a battery cell capacitance of 4 mAh/cm² at 2000 mAh/g.

FIG. 5 shows a further multistratum structure 16 produced with the method of the invention. Clearly recognizable are the copper substrate 14, the CuSiₓ adhesive layer 15, an indistinguishable 5-nm-thick carbon layer, and five strata of silicon 17, which alternate with strata of copper 18. The thickness of each newly applied copper stratum 18 increases toward the top. The accelerated annealing took place with a pulse duration of 1 ms, with a total of three flashes having been carried out, with variable energy, after strata 0, 3 and 5. In the bottommost stratum, the energy input in the accelerated annealing produced complete reaction of Cu and Si to form CuSi_{X}; in the upper strata, the energy input was selected for a sufficient partial reaction of Cu with Si to form CuSi_{X}.

### LIST OF REFERENCE SIGNS

1 lithium-ion battery
2 collector on anode side
3 SEI—solid-electrolyte interphase
4 electrolyte
5 separator
6 conducting interphase; CEI—cathode-electrolyte interphase
7 cathode, positive electrode
8 collector on cathode side
9 anode, negative electrode
10 sputtering of the Si layer
11 accelerated annealing, e.g., flash-lamp annealing or laser annealing
12 repetition of the process steps
13 sputtering of an additional material
14 copper substrate
15 adhesive layer
16 multistratum construction
17 silicon stratum, further silicon stratum
18 copper stratum
19 further stratum
20 metal layer

1. A method for producing a silicon electrode as anode for lithium batteries, wherein a first silicon layer is deposited on a substrate, preferably copper, and subsequently subjected to accelerated annealing, characterized in that the deposition of a further silicon layer and the subsequent accelerated annealing are repeated at least once.

2. The method as claimed in claim 1, characterized in that the deposition of a further silicon layer and the subsequent accelerated annealing are repeated twice or more than twice.

3. The method as claimed in claim 1, characterized in that before the deposition of the further silicon layer, a thin stratum of a further layer is applied, the thin stratum of the further layer being carbon, a metal, a metal oxide or a metal nitride.

4. The method as claimed in claim 3, characterized in that the thin stratum of the further layer is formed from one of the materials titanium (Ti), nickel (Ni), aluminum (Al), tin (Sn), gold (Au), silver (Ag), tungsten (W) and/or copper (Cu).

5. The method as claimed in claim 1, characterized in that the accelerated annealing is a flash-lamp annealing and is carried out by means of a flash lamp having a flash light duration of between 0.2 ms to 20 ms and an energy density of 0.6 J/cm² to 160 J/cm² and also of preheating or cooling in the range from 4° C. to 200° C.

6. The method as claimed in claim 1, characterized in that the accelerated annealing is a laser annealing and is carried out by means of a laser with an annealing time in the range from 0.01 ms to 100 ms by the establishment of a rate of scanning of a local heating site and an energy density in the range from 0.1 to 100 J/cm² and also of preheating or cooling in the range from 4° C. to 200° C.

7. The method as claimed in claim 1, characterized in that a metal layer is deposited onto the further silicon layer before the accelerated annealing.

8. The method as claimed in claim 5, characterized in that the metal layer is formed from one of the materials titanium (Ti), nickel (Ni), aluminum (Al), tin (Sn), gold (Au), silver (Ag) and/or tungsten (W).

9. The method as claimed in claim 1, characterized in that before the deposition of the first silicon layer on the copper substrate, a layer other than silicon is deposited, preferably nickel (Ni) and/or copper (Cu).
